(19) United States
(12) Patent Application Publication
(10) Pub. No.: US 2019/0100870 A1
(43) Pub. Date: Apr. 4, 2019

(54) MULTILAYERED FABRIC COMPOSED OF ALTERNATING CONDUCTIVE AND NONCONDUCTIVE LAYERS FOR EMI OR RF SHIELDING APPLICATIONS

(71) Applicant: Cerex Advanced Fabrics, Inc., Cantonment, FL (US)

(72) Inventor: Albert E. Ortega, Pensacola, FL (US)

(21) Appl. No.: 15/720,443

(22) Filed: Sep. 29, 2017

(51) Int. Cl. D06M 11/83; C23C 18/42; B32B 15/085; B32B 15/088; B32B 5/02; H05K 9/00

(52) U.S. Cl. CPC D06M 11/83; C23C 18/42; B32B 15/085; B32B 15/088; B32B 5/022; B32B 2307/202; H05K 9/0088; D10B 2401/16; B32B 2262/0253; B32B 2262/0261; B32B 2305/18; H05K 9/0084

(57) ABSTRACT

Fabrics for electromagnetic interference (EMI) and/or radio frequency (RF) shielding, along with methods of fabricating and using the same, are provided. A multilayer fabric with at least two different materials can be provided as a substrate for the fabrication of a fabric with alternating conductive and nonconductive layers. The fabric can be made with one layer of a second material between two layers a first material, which can be different from the second material. The layers made with the first material can be coated with a conductive material.

### BACKGROUND

Faraday cages can be made from fabrics coated with conductors. An example of the application of a Faraday cage for shielding is described in U.S. Pat. No. 5,136,119 to Leyland. A lightweight EMI shielding container is described in this patent, and copper-coated nylon nonwoven fabric is used to provide shielding. Another patent, U.S. Pat. No. 5,545,845 to Plummer et al. describes an electrical shielding chamber that uses a nickel/copper coating over a plain weave polyester taffeta fabric. Rip weave coated fabric may also be used.

The method of adherence of metal to fabric in a Faraday cage made from fabric can be performed in a number of ways. For example, copper can be adhered to nylon, carbon, acrylic, or polyester fabric, as described in U.S. Pat. No. 5,275,861 to Vaughn. Similarly, silver can be adhered to fabrics, as described in U.S. Pat. No. 5,186,984 to Gabbert and U.S. Patent Application Publication No. 2012/0129418 to Ingle. Each of these fabrics and methods has disadvantages.

### BRIEF SUMMARY

Embodiments of the subject invention provide fabrics and methods of fabricating and using the same that address limitations of existing Faraday cages made from fabrics. The related art methods discussed above do not provide a way to completely shield items from strong electromagnetic interference (EMI) or radio frequency (RF) signals, and a fabric that provides more protection from EMI and/or RF signals is needed. Embodiments of the subject invention provide such fabrics that protect from EMI and/or RF signals.

A multilayer fabric with at least two different materials can be provided as a substrate for the fabrication of a fabric with alternating conductive and nonconductive layers. The fabric can be made with one layer of a second material between two layers of fabric made from a first material, which can be different from the second material. The layers made with the first material can be coated with a conductive material. A multilayered fabric comprising alternating conductive and nonconductive layers can be provided by adhering a nonwoven of one polymer to another fabric or film of a different polymer. The fabric made from one of the materials can be coated with a conductive coating that provides EMI, shielding capability, RF shielding capability, or both. In an embodiment, the layer to be coated can be a nylon fabric, such as a nylon spunbond fabric. In a further embodiment, the nylon fabric can be coated with a conductive material (e.g., silver). In addition, the nonconductive layer can be a polypropylene layer, such as a melt blown polypropylene fabric.

In an embodiment, a nonwoven multilayered fabric can comprise a plurality of first layers comprising a first material, and at least one second layer comprising a second material that is nonconductive and is different from the first material. The first and second layers can be disposed in an alternating fashion such that each first layer is in direct physical contact with a second layer and physically separated from each other first layer. Also, each first layer can be coated with a conductive material.

In another embodiment, a method of fabricating a nonwoven multilayered fabric can comprise: fabricating two first layers comprising a first material; fabricating a second layer comprising a second material that is nonconductive and is different from the first material; adhering the second layer to both first layers such that the second layer is between the first layers and the first and second layers are disposed in an alternating fashion, wherein each first layer is in direct physical contact with the second layer and physically separated from the other first layer; and coating each first layer with a conductive material.

### BRIEF DESCRIPTION OF DRAWINGS

FIG. 1 is a cross-sectional view showing a plurality of alternating layers of a fabric according to an embodiment of the subject invention.

### DETAILED DESCRIPTION

Embodiments of the subject invention provide fabrics and methods of fabricating and using the same that address limitations of existing Faraday cages made from fabrics. Embodiments of the subject invention provide fabrics that protect from electromagnetic interference (EMI) and/or radio frequency (RF) signals. Articles used for EMI and/or RF shielding can be fabricated using the fabric.

Faraday cages can be made from fabrics coated with conductors (e.g., silver and copper). Related art fabric Faraday cages are limited in their level of performance because they do not completely eliminate the signal from which they are intended to shield. In embodiments of the subject invention, the addition of one or more Faraday cages can increase the shielding performance of the product because the leakage from the first Faraday cage can be shielded by the second cage and the leakage from the second cage can be shielded by the third cage and so on until complete elimination of the signal is achieved. The leakage from the Faraday cages can also be impacted by the strength of the signal. Stronger signals will require more Faraday cages to achieve elimination of the signal. In embodiments, a fabric that provides the ability to create multiple Faraday cages can be provided by combining fabric of different polymers that can be coated with metal. These fabrics made of different polymers can be laminated in alternating layers. The product can be such that metal will adhere to one type of polymer but not the other, thereby providing a laminate with alternating conductive and nonconductive layers.

A multilayer fabric with at least two different materials can be provided as a substrate for the fabrication of a fabric with alternating conductive and nonconductive layers. The fabric can be made with one layer of a second material between two layers of fabric made from a first material, which can be different from the second material. The layers made with the first material can be coated with a conductive material. A multilayered fabric comprising alternating conductive and nonconductive layers can be provided by adhering a nonwoven of one polymer to another fabric or film of a different polymer. The fabric made from one of the materials can be coated with a conductive coating that provides EMI shielding capability, RF shielding capability, or both. In an embodiment, the layer to be coated can be a nylon fabric, such as a nylon spunbond fabric. In a further embodiment, the nylon fabric can be coated with a conductive material (e.g., silver). In addition, the nonconductive layer can be a polypropylene layer, such as a melt blown polypropylene fabric.

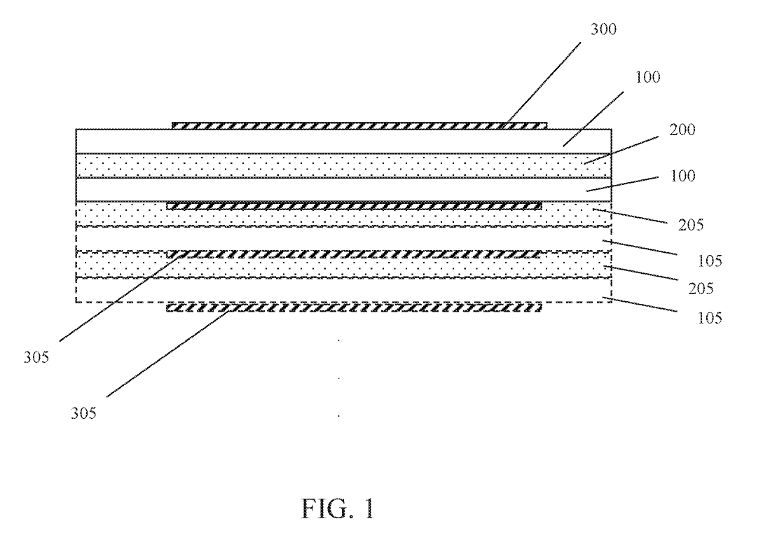

FIG. 1 is a cross-sectional view showing a plurality of alternating layers of a fabric according to an embodiment of the subject invention. Referring to FIG. 1, first 100 and second 200 (nonconductive) layers can be disposed in an alternating fashion, and each first layer 100 can have a conductive material 300 coated thereon. Any suitable number of additional first 105 and second 205 layers can be provided, with each first 105 layer having a conductive material 305 coated thereon. The conductive material 300,305 does not have to be the same for each first layer 100,105, nor does it even need to be limited to one type of conductive material on any single first layer. Also, it is important to note that FIG. 1 is provided for demonstrative purposes only and is not limiting. The shapes of each layer, and the location(s) and shape of the conductive material can be as depicted or can be different from what is shown in FIG. 1.

In a particular embodiment, two layers of a nylon spunbond fabric are combined with a polypropylene melt blown fabric by ultrasonically welding the polypropylene layer in between the two nylon layers. This fabric can have a basis weight of from (about) 45 grams per square meter (gsm) to (about) 300 gsm (for example, as measured by American Society for Testing and Materials (ASTM) D3776). This fabric can have an air permeability of from (about) 5 cubic feet per minute per square foot (ft³/min/ft²) to 100 ft³/min/ft² (for example, as measured by ASTM D737). Further embodiments of multilayer fabrics of the subject invention can have a basis weight or air permeability of any value or any subrange included within the ranges provided in this paragraph (with or without the term “about” before the value or one or both endpoints). The melt blown polypropylene layer can be replaced with a spunbond polypropylene or any fabric that will not be coated by the conductive material. Any suitable material can be used to create the nonconductive layer. Examples include films, spunbond fabrics, and melt blown fabrics. The ultrasonically welded laminate is then exposed to a conductive coating process that will adhere conductive material to the nylon layer but not the nonconductive layer (e.g., polypropylene layer). This will create a multilayer fabric with a conductive layer and a nonconductive layer (multiple such layers can be included, in an alternating fashion). Any suitable process can be used to adhere the layers together as long as holes are not created that would cause a short through the nonconductive layer, which would compromise it. Holes would allow conductivity through the nonconductive layer, essentially rendering one of the Faraday cages ineffective. Any suitable coating process can be used as long as the nonconductive layers (e.g., polypropylene layers) are not coated with conductive material. Adhering conductive material to the material of the nonconductive layer (e.g., polypropylene) would short the nonconductive layer and would not provide multiple Faraday cages. Any number of Faraday cages can be created by continuing to alternate conductive and nonconductive layers as described herein. The only possible limitation would be the ability to combine multiple layers.

In another embodiment, a nylon spunbond fabric can be coated with conductive material, such as copper or silver. A process for coating is described in U.S. Pat. No. 4,910,072 to Morgan et al. and U.S. Pat. No. 4,900,618 to O'Connor et al., both of which are incorporated herein by reference in their entirety. These metal-coated fabrics can then be adhered to alternating layers of a nonconductive fabric or film using any suitable means of lamination known in the art. In a specific embodiment of the subject invention, an adhesive web or film can be used to combine the layers.

A multilayered fabric used as a Faraday cage according to embodiments of the subject invention can have a basis weight of from (about) 45 gsm to (about) 600 gsm (for example, as measured by ASTM D3776), machine direction grab strength (for example, as measured by ASTM D5034) in a range of from (about) 10 pounds force (lb_{f}) to (about) 1000 lb_{f}, a cross direction grab strength (for example, as measured by ASTM D5034) in a range of from (about) 10 lb_{f} to (about) 1000 lb_{f}, a machine direction grab elongation (for example, as measured by ASTM D5034) in a range of from (about) 10% to (about) 200%, a cross direction grab elongation (for example, as measured by ASTM D5034) in a range of from (about) 10% to (about) 200%, a machine direction strip strength (for example, as measured by ASTM D5035) in a range of from (about) 10 lb_{f} to (about) 1000 lb_{f}, a cross direction strip strength (for example, as measured by ASTM D5035) in a range of from (about) 10 lb_{f} to (about) 1000 lb_{f}, a machine direction strip elongation (for example, as measured by ASTM D5035) in a range of from (about) 10% to (about) 200%, a cross direction strip elongation (for example, as measured by ASTM D5035) in a range of from (about) 10% to (about) 200%, and a thickness (for example, as measured by ASTM D1777) in a range of from (about) 1 mil to (about) 3000 mils. Further embodiments of multilayer fabrics of the subject invention can have a machine direction grab strength, cross direction grab strength, machine direction grab elongation, cross direction grab elongation, machine direction strip strength, cross direction strip strength, machine direction strip elongation, cross direction strip elongation, or thickness of any value or any subrange included within the ranges provided in this paragraph (with or without the term “about” before the value or one or both endpoints).

When the term “about” is used herein, in conjunction with a numerical value, it is understood that the value can be in a range of 95% of the value to 105% of the value, i.e. the value can be +/−5% of the stated value. For example, “about 1 kg” means from 0.95 kg to 1.05 kg. When the term “about” is used in parentheses before a numerical value, it should be understood as a shorthand way to express that the value can be the exact number (or endpoint) or can be about that number (or endpoint).

A greater understanding of the present invention and of its many advantages may be had from the following examples, given by way of illustration. The following examples are illustrative of some of the methods, applications, embodiments, and variants of the present invention. They are, of course, not to be considered as limiting the invention. Numerous changes and modifications can be made with respect to the invention.

### EXAMPLE 1

A multilayered fabric was provided with two outside layers of a 34 gsm thermally bonded spunbond nylon fabric, Style 30100, available from Cerex Advanced Fabrics, Inc. in Cantonment, Fla., and a 30 gsm polypropylene melt blown fabric in between the two layers. The three layers were ultrasonically bonded together to create a fabric that had a basis weight of 98 gsm as measured by ASTM D3776, an air permeability of 50.8 ft³/min/ft² as measured by ASTM D737, a machine direction grab strength of 66.1 lb_{f}, cross direction grab strength of 52.1 lb_{f}, machine direction grab elongation of 65%, and cross direction grab elongation of 71% all measured by ASTM D5034, a machine direction strip strength of 50.9 lb_{f}, cross direction strip strength of 31.1 lb_{f}, machine direction strip elongation of 62.3%, and cross direction strip elongation of 53.7% all measured by ASTM D5035, and a thickness of 25.9 mils as measured by ASTM D1777. This multilayered fabric was then coated with silver using a process that adheres silver to nylon substrates. This resulted in a fabric that had two outside layers of a conductive fabric and an inner layer of a nonconductive fabric.

### EXAMPLE 2

A multilayered fabric was provided with two outside layers of a 34 gsm thermally bonded spunbond nylon fabric, Style 30100, available from Cerex Advanced Fabrics, Inc. in Cantonment, Fla., and 60 gsm of polypropylene melt blown fabric in between the two layers. The three layers were ultrasonically bonded together to create a fabric that had a basis weight of 128 gsm as measured by ASTM D3776, an air permeability of 25.9 ft³/min/ft² as measured by ASTM D737, a machine direction grab strength of 66.6 pounds force (lb_{f}), cross direction grab strength of 52.5 lb_{f}, machine direction grab elongation of 60%, and cross direction grab elongation of 62% all measured by ASTM D5034, a machine direction strip strength of 52.2 lb_{f}, cross direction strip strength of 39.6 lb_{f}, machine direction strip elongation of 64.4%, and cross direction strip elongation of 61.0% all measured by ASTM D5035, and a thickness of 34.6 mils as measured by ASTM D1777. This multilayered fabric was then coated with silver using a process that adheres silver to nylon substrates. This resulted in a fabric that had two outside layers of a conductive fabric and an inner layer of a nonconductive fabric.

### EXAMPLE 3

Two layers of silver-coated 34 gm thermally bonded spunbond nylon fabric, style 30100, were adhered to opposite sides of a 34 gsm spunbond polypropylene fabric. The polypropylene fabric was identified as Unipro 100 and is available from MidWest Filtration in West Chester Township, Ohio. The three layers were combined together using a copolyamide adhesive web, 1G8 available from Protechnic. The adhesive web was melted using a household iron until all three layers were held together.

It should be understood that the examples and embodiments described herein are for illustrative purposes only and that various modifications or changes in light thereof will be suggested to persons skilled in the art and are to be included within the spirit and purview of this application and the scope of the appended claims.

All patents, patent applications, provisional applications, and publications referred to or cited herein are incorporated by reference in their entirety, including all figures and tables, to the extent they are not inconsistent with the explicit teachings of this specification.

What is claimed is:

1. A nonwoven multilayered fabric, comprising:
a plurality of first layers comprising a first material; and
at least one second layer comprising a second material that is nonconductive and is different from the first material,
wherein the first and second layers are disposed in an alternating fashion such that each first layer of the plurality of first layers is in direct physical contact with a second layer of the at least one second layer and physically separated from each other first layer of the plurality of first layers, and
wherein each first layer is coated with a conductive material.

2. The fabric according to claim 1, wherein the conductive material with which each first layer is coated is a metal.

3. The fabric according to claim 1, wherein the first material is nylon.

4. The fabric according to claim 1, wherein the first material is spunbond nylon.

5. The fabric according to claim 1, wherein the second material is polypropylene.

6. The fabric according to claim 1, wherein the first material is spunbond or melt blown nylon and the second material is spunbond or melt blown polypropylene.

7. The fabric according to claim 1, wherein the first material is spunbond nylon and the second material is melt blown polypropylene.

8. The fabric according to claim 1, wherein the first material is polyester.

9. The fabric according to claim 1, wherein each first layer of the plurality of first layers is adhered to a second layer of the at least one second layer, and wherein each second layer of the at least one second layer is adhered to a first layer of the plurality of first layers.

10. The fabric according to claim 1, wherein each second layer of the at least one second layer is a film.

11. The fabric according to claim 1, wherein the conductive material with which each first layer is coated is silver.

12. The fabric according to claim 1, wherein the fabric has a basis weight in a range of from 45 grams per square meter (gsm) to 300 gsm as measured by American Society for Testing and Materials (ASTM) D3776, and wherein the fabric has an air permeability in a range of from 5 cubic feet per minute per square foot (ft³/min/ft²) to 100 ft³/min/ft² as measured by ASTM D737.

13. The fabric according to claim 1, wherein the conductive material with which each first layer is coated is a metal,
wherein the first material is spunbond or melt blown nylon,
wherein the second material is spunbond or melt blown polypropylene,
wherein each first layer of the plurality of first layers is adhered to a second layer of the at least one second layer, and each second layer of the at least one second layer is adhered to a first layer of the plurality of first layers,
wherein the fabric has a basis weight in a range of from 45 gsm to 300 gsm as measured by ASTM D3776, and
wherein the fabric has an air permeability in a range of from 5 ft³/min/ft² to 100 ft³/min/ft² as measured by ASTM D737.

14. The fabric according to claim 13, wherein the conductive material with which
